(19) United States
(12) Patent Application Publication
(10) Pub. No.: US 2025/0210476 A1
(43) Pub. Date: Jun. 26, 2025

(54) SEMICONDUCTOR MODULE

(71) Applicant: FUJI ELECTRIC CO., LTD., Kawasaki-shi (JP)

(72) Inventor: Koji OSAKI, Matsumoto-city (JP)

(73) Assignee: FUJI ELECTRIC CO., LTD., Kawasaki-shi, Kanagawa (JP)

(21) Appl. No.: 18/930,506

(22) Filed: Oct. 29, 2024

(30) Foreign Application Priority Data
Dec. 26, 2023 (JP) 2023-219633

(51) Int. Cl. H01L 23/495; H01L 23/00; H01L 23/31; H01L 23/367; H05K 1/18

(52) U.S. Cl. CPC H01L 23/49558; H01L 23/3121; H01L 23/49562; H01L 23/49586; H01L 24/32; H01L 23/3672; H01L 23/562; H01L 2224/32245; H01L 2924/1815; H05K 1/181

(57) ABSTRACT

A semiconductor module, including: a stacked substrate having, at a top surface thereof, a conductive plate; a semiconductor chip having a front surface and a back surface opposite to each other, the back surface being bonded to the top surface of the stacked substrate, the semiconductor chip having a front electrode at the front surface; a lead frame electrically connecting the front electrode and the conductive plate to each other, the lead frame having a first surface and a second surface opposite to each other, the second surface facing the stacked substrate; an encapsulating material encapsulating the semiconductor chip, the stacked substrate, and the lead frame; and an insulating layer provided on the lead frame, and facing the first surface of the lead frame in a thickness direction. The insulating layer contains an electrical insulating material having an elastic modulus smaller than that of the encapsulating material.

### CROSS REFERENCE TO RELATED APPLICATIONS

This application is based upon and claims the benefit of priority of the prior Japanese Patent Application No. 2023-219633, filed on Dec. 26, 2023, the entire contents of which are incorporated herein by reference.

### BACKGROUND OF THE INVENTION

### 1. Field of the Invention

Embodiments of the invention relate to a semiconductor module.

### 2. Description of the Related Art

Japanese Laid-Open Patent Publication No. 2019-96643 describes a technique for increasing the strength of a surface electrode of a semiconductor chip and extending the life during power cycling evaluation of the semiconductor chip or a power module. Japanese Laid-Open Patent Publication No. 2023-15214 also describes a similar technique. Japanese Laid-Open Patent Publication No. 2018-46164 describes a technique for reducing stress applied to a bonding portion and extending fatigue life in a power cycling test, the bonding portion being bonded to an electrode pattern of lead frame wiring.

### SUMMARY OF THE INVENTION

According to an embodiment of the present disclosure, a semiconductor module includes: a stacked substrate having, at a top surface thereof, a conductive plate; a semiconductor chip having a front surface and a back surface opposite to each other, the back surface being bonded to the top surface of the stacked substrate, the semiconductor chip having a front electrode at the front surface; a lead frame electrically connecting the front electrode and the conductive plate to each other, the lead frame having a first surface and a second surface opposite to each other, the second surface facing the stacked substrate; an encapsulating material encapsulating the semiconductor chip, the stacked substrate, and the lead frame; and an insulating layer provided on the lead frame, and facing the first surface of the lead frame in a thickness direction of the semiconductor chip. The insulating layer contains an electrical insulating material having an elastic modulus smaller than an elastic modulus of the encapsulating material.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting an example of a layout when a semiconductor module according to a first embodiment is viewed from a front surface of a circuit board thereof.

FIG. 2 is an enlarged view of a portion A surrounded by a rectangle in FIG. 1.

FIG. 3 is a cross-sectional view schematically depicting a structure along cutting line B-B′ in FIG. 1.

FIG. 4 is a cross-sectional view schematically depicting another example of the structure along cutting line B-B′ in FIG. 1.

FIG. 5 is a cross-sectional view depicting a structure of a semiconductor module according to a second embodiment.

FIG. 6 is a cross-sectional view depicting the structure of the semiconductor module according to the second embodiment.

FIG. 7 is a cross-sectional view depicting another example of the structure of the semiconductor module according to the second embodiment.

FIG. 8 is a cross-sectional view depicting another example of the structure of the semiconductor module according to the second embodiment.

FIG. 9 is a cross-sectional view depicting a structure of a semiconductor module according to a third embodiment.

FIG. 10 is a graph showing results of simulation of the amount of strain of a front electrode of a semiconductor chip in an example and a reference example.

FIG. 11A is a contour diagram depicting results of simulation of a state during deformation caused by thermal stress of members in a semiconductor module of the reference example.

FIG. 11B is a contour diagram depicting results of simulation of a state during deformation caused by thermal stress of members in the semiconductor module of the example.

FIG. 12 is a characteristics diagram depicting results of simulation of a relationship between the strain amount of the front electrode of the semiconductor chip and thickness of respective insulating layers of the example and the reference example.

FIG. 13 is a cross-sectional view depicting a structure of a semiconductor device of the reference example.

FIG. 14 is a diagram schematically depicting a state during deformation due to thermal stress of the members inside the semiconductor module of the reference example.

### DETAILED DESCRIPTION OF THE INVENTION

First, problems associated with the conventional techniques are discussed. in Japanese Laid-Open Patent Publication No. 2019-96643, a lead terminal is fixed at a position by an encapsulating material and thus, when the semiconductor chip thermally expands during a power cycling test, a portion of the lead terminal rising from a front surface of semiconductor chip becomes deformed. Strain occurs in a front electrode of the semiconductor chip due to adverse effects of the deformation of the rising portion of the lead frame, which may lead to destruction. In Japanese Laid-Open Patent Publication No. 2023-15214, the structure also employs a lead member and problems similar to the problems of Japanese Laid-Open Patent Publication No. 2019-96643 occur. In Japanese Laid-Open Patent Publication No. 2018-46164, problems similar to the problems of Japanese Laid-Open Patent Publication No. 2019-96643 occur.

Here, an outline of an embodiment of the present disclosure is described. (1) A semiconductor module according to an embodiment of the present disclosure has the following features. A stacked substrate having at a top surface thereof, a conductive plate. A semiconductor chip, a back surface thereof being bonded to the top surface of the stacked substrate and a front surface thereof having a front electrode. A lead frame electrically connecting the front electrode and the conductive plate to each other. An encapsulating material encapsulating the semiconductor chip, the stacked substrate, and the lead frame. An insulating layer provided facing a first surface of the lead frame in a thickness direction of the semiconductor chip, the first surface being opposite to a second surface of the lead frame, the second surface facing the stacked substrate. The insulating layer containing an electrical insulating material having an elastic modulus smaller than an elastic modulus of the encapsulating material.

According to the disclosure above, support of the lead frame by the encapsulating material is reduced by the insulating layer provided facing the lead frame and thus, even when stress is generated that pushes a rising portion of the lead frame upward due to thermal expansion of the semiconductor chip, the rising portion of the lead frame easily moves upward and is not easily deformed. As a result, concentration of stress at an end of the front electrode of the semiconductor chip does not easily occur and the amount of strain on the end of the front electrode of the semiconductor chip may be reduced and thus, power cycling capability may be enhanced.

(2) Further, in the semiconductor module according to the present disclosure, in (1) above, the insulating layer may face an entire area of the lead frame.

According to the disclosure above, the larger is the area of the lead frame that the insulating layer faces in the thickness direction of the semiconductor chip, the higher is the effect obtained by the insulating layer.

(3) Further, in the semiconductor module according to the present disclosure, in (1) or (2) above, the insulating layer may be in contact with the lead frame.

According to the disclosure above, the closer is the insulating layer to the lead frame in the thickness direction of the semiconductor chip, the higher is the effect obtained by the insulating layer.

(4) Further, in the semiconductor module according to the present disclosure, in any one of (1) to (3) above, the insulating layer may have a thickness in a range of 0.2 mm to 0.5 mm.

According to the disclosure above, the thicker is the thickness of the insulating layer provided facing the lead frame, the higher is the effect obtained by the insulating layer.

(5) Further, in the semiconductor module according to the present disclosure, in any one of (1) to (4) above, the lead frame has: a bonding portion bonded to the front electrode and having a plate-like shape; a rising portion formed by bending the lead frame upward from an end of the bonding portion, the rising portion having a plate-like shape having a first end and a second end opposite to each other, the first end being the end of the bonding portion; and a connecting portion formed by bending the lead frame from the second end of the rising portion, the connecting portion having a plate-like shape, an end of the connecting portion being the second end of the rising portion, the connecting portion electrically connecting the second end of the rising portion and the conductive plate. The insulating layer may face the second end of the rising portion in the thickness direction of the semiconductor chip.

According to the disclosure above, the insulating layer is disposed so as to at least face the second end of the rising portion in the thickness direction of the semiconductor chip, whereby an effect by the insulating layer is obtained.

(6) Further, in the semiconductor module according to the present disclosure, in (5) above, the insulating layer may be in contact with an entire first surface of the connecting portion, the first surface being opposite to a second surface of the connecting portion, the second surface facing the stacked substrate.

According to the disclosure above, the larger is the area of the lead frame that the insulating layer faces in the thickness direction of the semiconductor chip, the higher is the effect obtained by the insulating layer.

(7) Further, in the semiconductor module according to the present disclosure, in (6) above, the insulating layer may extend from the connecting portion, along the rising portion to a non-bonding surface of the bonding portion, the non-bonding surface being opposite to a bonding surface of the bonding portion, the bonding surface being bonded to the front electrode.

According to the disclosure above, for example, a sheet-like electrical insulating material may be used to form the insulating layer so as to cover a top surface of the lead frame and an assembly process may be simplified.

(8) Further, in the semiconductor module according to the present disclosure, in (5) above, the insulating layer may be provided only at the second end of the rising portion.

According to the disclosure above, for example, a sheet-like electrical insulating material may be used to form the insulating layer so as to cover only the second end of the rising portion, thereby simplifying the assembly process.

(9) Further, in the semiconductor module according to the present disclosure, in (8) above, the second end of the rising portion may have a hook-shaped part sandwiching the insulating layer with the lead frame.

According to the disclosure above, for example, when a sheet-like electrical insulating material is used to form the insulating layer, the insulating layer may be prevented from falling during the assembly process.

Here, a semiconductor module of a reference example is described. FIG. 13 is a cross-sectional view depicting a structure of a semiconductor device of the reference example. A semiconductor module 110 of the reference example depicted in FIG. 13 has a structure in which one or more semiconductor chips 101 and/or components (not depicted) are incorporated as a single unit (functional unit) therein and, for example, the semiconductor module 110 is used in power converting equipment and the like. A surface electrode (hereinafter, back electrode, not depicted) at a back surface of the semiconductor chip 101 is bonded to a conductive plate 122 (122a) constituting a front surface of a circuit board 102, via a bonding member 111.

The conductive plate 122 (122a, 122b) configures a circuit pattern of the circuit board 102. A metal foil 123 at a back surface of the circuit board 102 is bonded to a front surface of a cooling base 103, via a bonding member 112. The circuit board 102 is a stacked substrate in which the conductive plate 122 and the metal foil 123 are provided, respectively, on opposite sides of an insulated substrate 121. A case 104 containing resin is adhered to an outer edge of the cooling base 103. The cooling base 103 and the case 104 form a recess 107 having a box-like shape in which the circuit board 102 is housed.

A lead frame (LF) 105 is bonded to a surface electrode (hereinafter, front electrode, not depicted) at a front surface of the semiconductor chip 101, via a bonding member 113. Further, the LF 105 is bonded, via a bonding member 114, to the conductive plate 122 (122b) constituting the front surface of the circuit board 102. The LF 105 is a flat conductive wiring member. The LF 105 has a LF bonding portion 105a, a LF rising portion 105b, and a LF connecting portion 105c.

Of the LF 105, the LF bonding portion 105a is a portion bonded to an electrode pad (front electrode or the conductive plate 122b) at the front surface of the circuit board 102 and has a flat, substantially rectangular surface parallel to a surface of the electrode pad. The LF bonding portion 105a is provided for each electrode pad at the front surface of the circuit board 102. The LF rising portion 105b has a flat, substantially rectangular shaped surface and is formed by bending the LF 105 from an end (one edge) of the LF bonding portion 105a, in a direction substantially orthogonal to the LF bonding portion 105a. The LF rising portion 105b is provided for each LF bonding portion 105a.

The LF connecting portion 105c has a flat, substantially rectangular shaped surface and is formed by bending the LF 105 from an end (one edge constituting an upper end 105b-1) of the LF rising portion 105b, in a direction substantially orthogonal to the LF rising portion 105b; the LF connecting portion 105c connects the LF rising portions 105b that are adjacent to each other. The LF 105 extends between adjacent electrode pads so as to include a substantially Z-shape in a cross-sectional view, the Z-shape being formed by a bent portion (right-angle portion) at a boundary between the LF bonding portion 105a and the LF rising portion 105b and having a substantially L-shape, and a bent portion formed at a boundary between the LF rising portion 105b and the LF connecting portion 105c and having a substantially L-shape.

The recess 107 is filled with an encapsulating material 106 containing a resin such as a silicone gel. The encapsulating material 106 covers all members housed in the recess 107 and surrounds peripheries of all the members. The encapsulating material 106 covers and electrically insulates a side surface (creepage of the insulated substrate 121 and end of the metal foil 123) of the circuit board 102, the semiconductor chip 101 at the front surface of the circuit board 102, the conductive plate 122, side surfaces of bonding members 111, 112, 113, 114, and the LF 105, from the external environment, the encapsulating material 106 having a function of providing mechanical, physical, and chemical protection from the external environment.

In the semiconductor module 110 of the reference example, during a power cycling test, the semiconductor chip 101 and members in a vicinity thereof are deformed and the front electrode of the semiconductor chip 101 becomes a point of failure. The power cycling test is a test for evaluating the reliability of bonding between the members in the semiconductor module 110, and in the power cycling test, the junction temperature of a semiconductor device fabricated in the semiconductor chip 101 is caused to repeatedly increase (self-heating of the semiconductor chip 101) and decrease (natural heat dissipation: cooling of the semiconductor chip 101) within a predetermined temperature difference (change) ΔTᵥⱼ by intermittently energizing the semiconductor device.

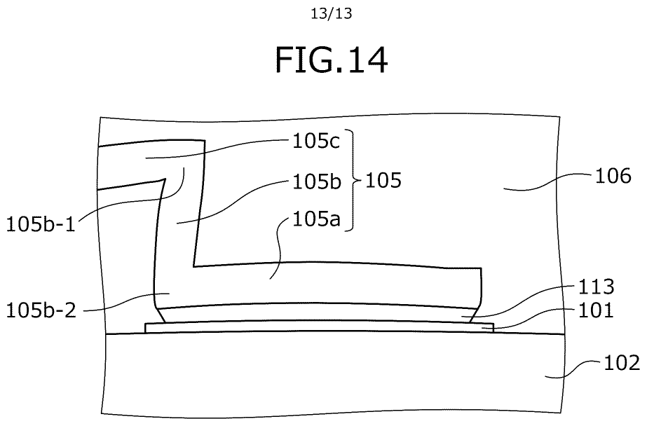

A mechanism of the deformation of the semiconductor chip 101 and the members in a vicinity thereof inside the semiconductor module 110 of the reference example is described. FIG. 14 is a diagram schematically depicting a state during deformation due to thermal stress of the members inside the semiconductor module of the reference example. FIG. 14 schematically depicts a state in which in the power cycling test, heat generation and cooling of the semiconductor chip 101 is repeatedly performed, whereby the semiconductor chip 101 and the members (the bonding member 113 and the LF 105) in a vicinity thereof inside the semiconductor module 110 are subject to stress resulting from heat stress and become deformed.

As depicted in FIG. 14, when the semiconductor chip 101 generates heat due to energization of the semiconductor device fabricated in the semiconductor chip 101, the front electrode of the semiconductor chip 101 (not depicted), the bonding member 113, and the LF bonding portion 105a thermally expand in a vertical direction (thickness direction of the semiconductor chip 101) and top surfaces thereof move upward (direction away from the circuit board 102). Meanwhile, the LF rising portion 105b is supported by the encapsulating material 106 and thus, the position of the LF rising portion 105b becomes fixed, the LF rising portion 105b does not move significantly and is pressed by the semiconductor chip 101, becoming bent, whereby a height (length) of the LF rising portion 105b decreases.

During cooling of the semiconductor chip 101, the encapsulating material 106 cools, shrinks, is plastically deformed, and pushes the semiconductor chip 101, the bonding member 113, and the LF bonding portion 105a downward (a direction toward the circuit board 102). As described above, the LF rising portion 105b is supported by the encapsulating material 106 and does not substantially move. In addition, the length of the LF rising portion 105b is shortened. Thus, the end of the front electrode of the semiconductor chip 101 is pulled upward by the LF rising portion 105b, putting strain on the end of the front electrode of the semiconductor chip 101.

When heat generation and cooling of the semiconductor chip 101 are alternately repeated, compressive stress and tensile stress are alternately applied repeatedly to the front electrode of the semiconductor chip 101 and the bonding member 113 directly beneath a lower end (end facing the circuit board 102) 105b-2 of the LF rising portion 105b. Thus, directly beneath the lower end 105b-2 of the LF rising portion 105b, the front electrode of the semiconductor chip 101 and the bonding member 113 degrade, leading to destruction. In light of these problems, in the present embodiments, power cycling capability is enhanced.

Embodiments of a semiconductor module according to the present disclosure are described in detail with reference to the accompanying drawings. In the description and accompanying drawings of the embodiments, parts that are the same are given the same reference numerals and are not repeatedly described.

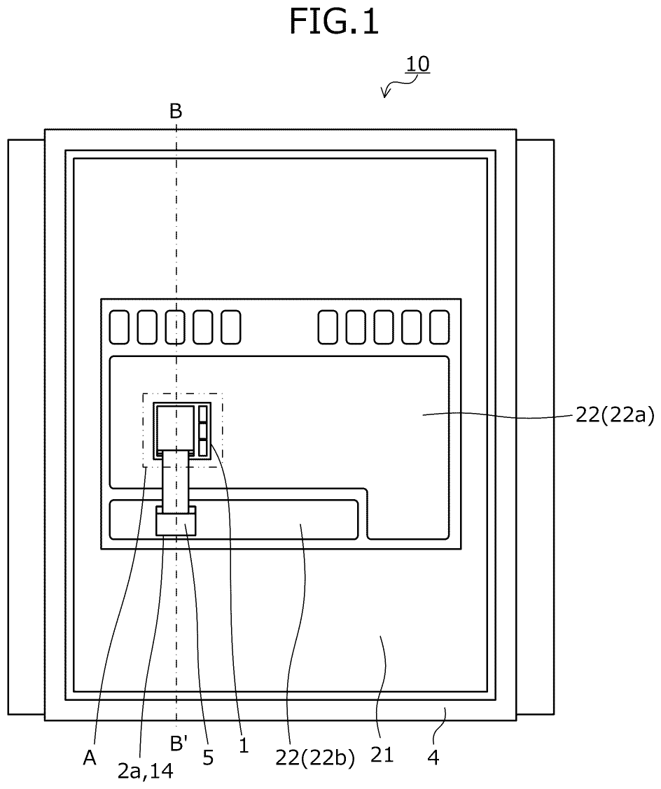

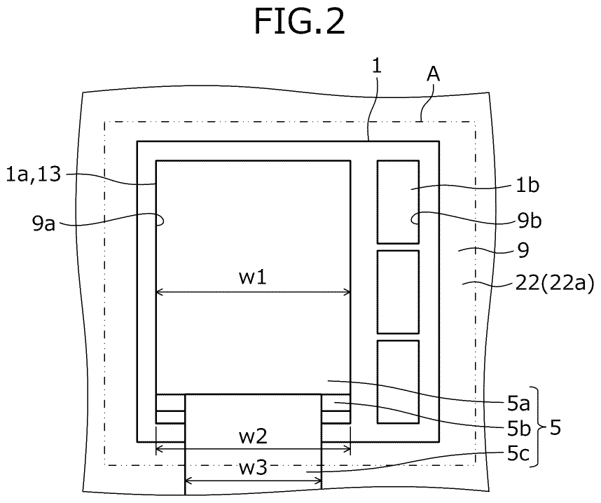

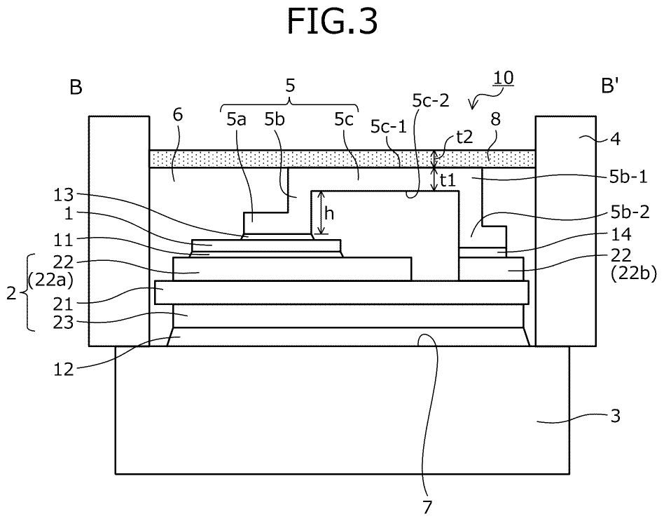

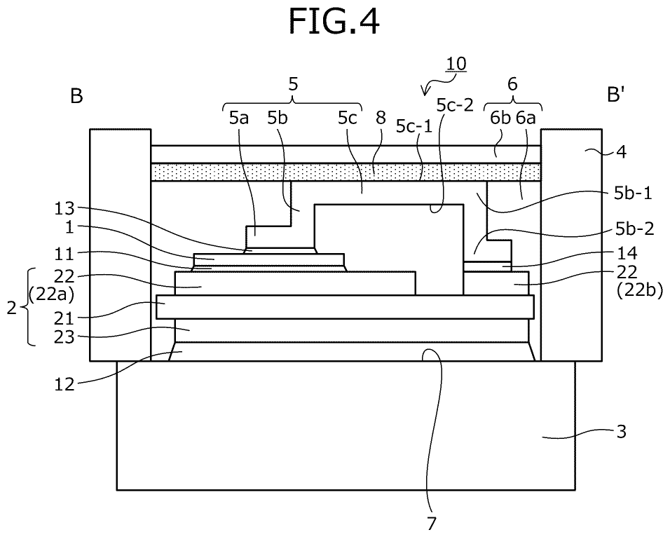

A semiconductor module according to a first embodiment is described. FIG. 1 is a plan view depicting an example of a layout when the semiconductor module according to the first embodiment is viewed from a front surface of a circuit board thereof. FIG. 2 is an enlarged view of a portion A surrounded by a rectangle in FIG. 1. FIG. 2 depicts an enlarged view of a semiconductor chip 1 and a LF bonding portion 5a in FIG. 1. FIG. 3 is a cross-sectional view schematically depicting a structure along cutting line B-B′ in FIG. 1. FIG. 4 is a cross-sectional view schematically depicting another example of the structure along cutting line B-B′ in FIG. 1. FIGS. 3 and 4 depict members of dimensions different from dimensions thereof in FIG. 1, the members being in a semiconductor module 10.

The semiconductor module 10 according to the first embodiment depicted in FIGS. 1 to 3 has a structure in which one or more of the semiconductor chips 1 and/or components (not depicted) are incorporated therein as a single unit (functional unit) and, for example, the semiconductor module 10 is used in power converting equipment and the like. A material of the semiconductor chip 1 may be, for example, silicon (Si) or silicon carbide (SiC). In the semiconductor chip 1, one or more semiconductor devices are fabricated that configure all or a portion of functions such as conversion (conversion of input signals such as frequency, current, voltage), connection (on/off of external components), etc. At a front surface of the semiconductor chip 1, a surface electrode (front electrode: not depicted) of the semiconductor device is provided.

As for a semiconductor device fabricated in the semiconductor chip 1, examples include a metal oxide semiconductor field effect transistor (MOSFET) having an insulated gate with a three-layer metal-oxide-semiconductor structure, an insulated gate bipolar transistor (IGBT), and a diode. The front electrode of the semiconductor chip 1 is, for example, a source electrode of a MOSFET, an emitter electrode of an IGBT, or an anode electrode of a diode.

The front surface of the semiconductor chip 1 is covered by a passivation film 9. The front electrode has a portion that is exposed in an opening 9a of the passivation film 9 and functions as an electrode pad 1a. In other openings 9b of the passivation film 9, an electrode pad 1b not bonding a later-described LF 5 may be exposed. A surface electrode (back electrode: not depicted) at a back surface of the semiconductor chip 1 is bonded to a conductive plate 22 (22a) of a front surface (top surface) of the circuit board 2, via a bonding member 11. The conductive plate 22 (22b) partially functions as an electrode pad 2a. The conductive plate 22 (22a, 22b) configures a circuit pattern of the circuit board 2.

A metal foil 23 at a back surface of the circuit board 2 is bonded to a front surface of a cooling base 3, via a bonding member 12. The circuit board 2 is a stacked substrate in which the conductive plate 22 and the metal foil 23 are provided, respectively, on opposite sides of an insulated substrate 21. The cooling base 3 is a conductive heat sink that conducts heat generated by the semiconductor chip 1 and transferred via the circuit board 2, the cooling base 3 conducting the heat to heat dissipation fins (not depicted). The heat dissipation fins are bonded to a back surface of the cooling base 3. At an outer edge of the cooling base 3, a case 4 made of resin is adhered. The insulated substrate 21 is provided in the case 4. The case 4 may be apart from an outer edge of the insulated substrate 21 and a gap may be present between the case 4 and the insulated substrate 21. The case 4 may be adhered at least partially in contact with the outer edge of the insulated substrate 21. The circuit board 2 is housed in a box-shaped recess 7 bordered by the cooling base 3 and the case 4.

The lead frame (LF) 5 is bonded to the front electrode (the electrode pad 1a) of the semiconductor chip 1, via a bonding member 13. Further, the LF 5 is bonded to the conductive plate 22b (the electrode pad 2a) of the front surface of the circuit board 2, via a bonding member 14. The LF 5 supports and fixes the semiconductor chip 1 to the circuit board 2, and electrically connects the front electrode of the semiconductor chip 1 and external-lead wiring (not depicted) of the semiconductor module 10. The LF 5 is a flat conductive wiring member formed by pressing, bending, etching, etc. a flat copper-based plate containing for example, a copper (Cu) alloy having excellent conductivity.

The LF 5 is bonded to the front electrode of the semiconductor chip 1 (for example, a front electrode of a semiconductor device that performs a main operation of the semiconductor chip 1); the LF 5 has functions of energizing the semiconductor chip 1 and dissipating heat generated by the semiconductor chip 1. The LF 5 is used, whereby, size reductions of the semiconductor module 10 are facilitated as compared to wire bonding of electrically connecting the front electrode of the semiconductor chip 1 and the external-lead wiring to each other by a wire. Further, the LF 5 may be integrated with and bonded to multiple parts (the electrode pads 1a, 2a) and thus, the assembly process may be simplified as compared to wire bonding in which multiple wires are bonded to each of the electrode pads 1a, 2a.

The LF 5 has the LF bonding portion 5a, an LF rising portion 5b, and an LF connecting portion 5c. A thickness t1 of the LF 5 is, for example, about 0.5 mm. The LF 5 extends between the semiconductor chips 1 (i.e., between the electrode pads 1a) that are adjacent to each other or extends between the semiconductor chip 1 and the conductive plate 22b (that is, between the electrode pads 1a, 2a) that are adjacent to each other, so as to include, in a cross-sectional view, a substantially Z-shape having a bent portion (a substantially L-shaped right-angle portion or a substantially V-shaped obtuse angle portion) at a boundary between the LF bonding portion 5a and the LF rising portion 5b and having a bent portion at a boundary between the LF rising portion 5b and the LF connecting portion 5c.

In the LF 5, the LF bonding portion 5a is a portion thereof bonded to surfaces of the electrode pads 1a, 2a (the front electrode of the semiconductor chip 1, the conductive plate 22b) at the front surface of the circuit board 2 and has a flat, substantially rectangular shaped surface parallel to the front surface of the semiconductor chip 1. A bonding surface (lower surface) of the LF bonding portion 5a has, for example, a surface area substantially a same as a surface area of the electrode pads 1a, 2a and covers substantially an entire area of the surfaces of the electrode pads 1a, 2a via the bonding members 13, 14. The smaller is the surface area of the LF bonding portion 5a, the lower is the heat dissipation of the semiconductor chip 1 and thus, the usefulness of the present disclosure is high. The LF bonding portion 5a is provided for each of the electrode pads 1a, 2a at the front surface of the circuit board 2. The LF bonding portion 5a has a width (width in a lateral direction) w1 that is, for example, about 3.0 mm.

The LF rising portion 5b is formed by bending the LF 5 from an end (one edge) of the LF bonding portion 5a, in a direction substantially orthogonal to the LF bonding portion 5a, the LF rising portion 5b having a flat, substantially rectangular shaped surface sharing one edge (a lower end 5b-2 of the LF rising portion 5b) with the LF bonding portion 5a. The LF rising portion 5b is provided for each of the LF bonding portions 5a. The LF rising portion 5b may be tilted at an angle in a range of 45 degrees to less than 90 degrees with respect to the front surface of the semiconductor chip 1, so as to form an obtuse angle with the LF bonding portion 5a. In other words, a top surface (non-bonding surface opposite to the surface facing the circuit board 2) of the LF bonding portion 5a and a flat surface of the LF rising portion 5b form an angle within a range of 90 degrees to 135 degrees. An upper limit of a height (length) h of the LF rising portion 5b is suitably set according to a height (depth of the recess 7) of the case 4.

The higher is the height h of the LF rising portion 5b, the more likely the LF rising portion 5b is adversely affected by the heat generated by the semiconductor chip 1 and therefore, usefulness of the present disclosure is high. When the height h of the LF rising portion 5b is too low, a later-described encapsulating material 6 may not fill a space between the LF rising portion 5b and the circuit board 2. Therefore, preferably, the height h of the LF rising portion 5b may be, for example, about 2.0 mm or more. The height h of the LF rising portion 5b is a distance in a vertical direction from top surfaces of the bonding members 13, 14 to a lower surface (surface facing the circuit board 2) 5c-2 of the LF connecting portion 5c. A width (width in a lateral direction) w2 of the LF rising portion 5b is, for example, substantially about a same as the width w1 of the LF bonding portion 5a.

The LF connecting portion 5c is formed by bending the LF 5 from an upper end (one edge constituting a first end opposite to a second end facing the circuit board 2) 5b-1 of the LF rising portion 5b, the LF connecting portion 5c having flat, substantially rectangular shaped surfaces (top surface 5c-1 and a lower surface 5c-2) sharing one edge (the upper end 5b-1 of the LF rising portion 5b) with the LF rising portion 5b. The LF connecting portion 5c connects the LF rising portions 5b that are adjacent to each other. A flat surface of the LF connecting portion 5c is substantially parallel to a flat surface of the LF bonding portion 5a. An angle formed by the lower surface 50-2 of the LF connecting portion 5c and the flat surface of the LF rising portion 5b is substantially a same as an angle formed by the top surface of the LF bonding portion 5a and the flat surface of the LF rising portion 5b. A width (width in a lateral direction) w3 of the LF connecting portion 5c may be narrower (for example, about 2.5 mm) than the width w1 of the LF bonding portion 5a.

The encapsulating material 6 containing a resin such as a silicone gel fills the recess 7, from a bottom (the front surface of the cooling base 3) of the recess 7 to a predetermined height. The encapsulating material 6 fills the recess 7, from the bottom of the recess 7 to at least a height of the top surface of the LF bonding portion 5a. As a result, the bonding members 11 to 14, which are relatively easily affected adversely by the external environment, are covered and protected by the encapsulating material 6. Thus, the encapsulating material 6 covers at least exposed portions (end of the insulated substrate 21 and end of the metal foil 23) of the circuit board 2, the conductive plate 22 and the semiconductor chip 1 of the front surface of the circuit board 2, exposed portions (in FIG. 1, side surfaces) of the bonding members 11 to 14, and a side surface of the LF bonding portion 5a and thereby provides electrical insulation from the external environment and has a function of providing mechanical, physical, and chemical protection from the external environment.

Preferably, the encapsulating material 6 may fill the recess 7, from the bottom of the recess 7 to, for example, at least a height of the top surface 5c-1 of the LF connecting portion 5c and encapsulate the top surface of the LF bonding portion 5a, the LF rising portion 5b, and a side surface and the lower surface 5c-2 of the LF connecting portion 5c (FIG. 3). Increasing a height of a top surface of the encapsulating material 6 increases respective portions of the top surface of the LF bonding portion 5a, the LF rising portion 5b, and the side surface and the lower surface 5c-2 of the LF connecting portion 5c protected mechanically, physically, and chemically from the external environment by the encapsulating material 6. A later-described insulating layer 8 may be provided thickly on the encapsulating material 6 to surround the top surface of the LF bonding portion 5a, the LF rising portion 5b, the side surface and the lower surface 5c-2 of the LF connecting portion 5c with the insulating layer 8.

In the recess 7, the insulating layer (hatched portion) 8 is further provided on the encapsulating material 6. The insulating layer 8 is provided on a first side of the LF 5, opposite a second side thereof facing the circuit board 2, the insulating layer 8 being provided on the top surface 5c-1 of the LF connecting portion 5c so as to at least face the upper end 5b-1 of the LF rising portion 5b in the vertical direction (thickness direction of the semiconductor chip 1). The insulating layer 8 may face the top surface 5c-1 of the LF connecting portion 5c in the vertical direction, via the encapsulating material 6. The insulating layer 8 having a substantially uniform thickness, may extend parallel to the front surface of the circuit board 2 and be in contact with a sidewall (inner wall of the case 4) of the recess 7. FIG. 3 depicts a state in which the encapsulating material 6 fills the recess 7 to a height substantially a same as the height of the top surface 5c-1 of the LF connecting portion 5c and the insulating layer 8 covers an entire area of the surface of the encapsulating material 6 and faces the LF 5 overall.

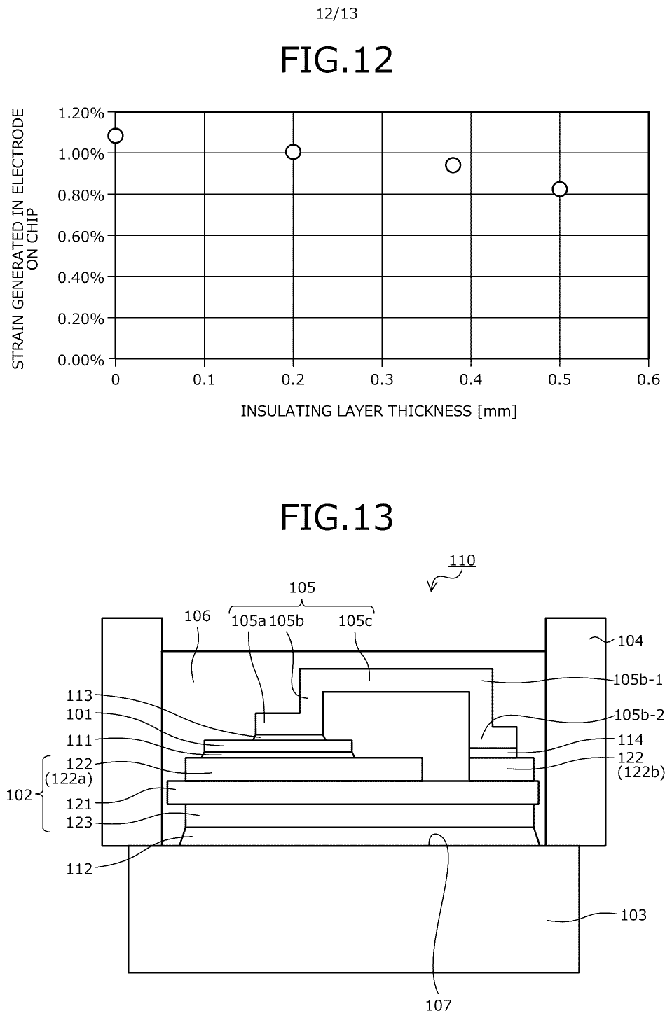

Preferably, a portion of the insulating layer 8 facing the top surface 5c-1 of the LF connecting portion 5c in the vertical direction has, for example, a thickness t2 in a range of about 0.2 mm to 0.5 mm (refer to later-described FIG. 12). The portion of the insulating layer 8 facing the top surface 5c-1 of the LF connecting portion 5c in the vertical direction suffices to have the thickness t2 and a height of a lower surface (i.e., the top surface of the encapsulating material 6) of the insulating layer 8 may be suitably set in a range up to a height of the top surface of the LF bonding portion 5a, in a direction to the circuit board 2. Preferably, in a plan view, the insulating layer 8 may have outer dimensions that are at least a same as outer dimensions (width w3 and length) of the top surface 5c-1 of the LF connecting portion 5c and may face an entire area of the top surface 5c-1 of the LF connecting portion 5c. The greater are the dimensions of the insulating layer 8 in a plan view, the greater is the effect of the insulating layer 8.

The insulating layer 8 has a function of reducing the strength of support of the LF rising portion 5b by the encapsulating material 6 and facilitating movement of the LF rising portion 5b corresponding to the stress applied to the LF rising portion 5b. The insulating layer 8 faces the upper end 5b-1 of the LF rising portion 5b in the vertical direction and thus, movement of the LF rising portion 5b in the vertical direction may be facilitated by the insulating layer 8. Movement of the LF rising portion 5b in the vertical direction may be facilitated by the insulating layer 8 and thus, even when stress is applied to the LF rising portion 5b in the vertical direction due to expansion of the front electrode caused by self-heating of the semiconductor chip 1, a concentration of stress at the lower end (one edge constituting an end facing the circuit board 2) 5b-2 of the LF rising portion 5b may be suppressed.

Further, the insulating layer 8 has a function of electrically insulating the LF 5 from the external environment and providing mechanical, physical, and chemical protection from the external environment. In other words, members housed in the recess 7 are surrounded and protected by the encapsulating material 6 or the insulating layer 8, or both. The insulating layer 8 is formed by an insulating material that is softer (has a lower hardness) than the encapsulating material 6. An elastic modulus of the insulating layer 8 is smaller than an elastic modulus (for example, about 20 GPa) of the encapsulating material 6 and, for example, is in a range of about 3 GPa to 10 GPa. In particular, the insulating layer 8 suffices to be made of a material having electrical insulating properties and, for example, is formed of a resin material such as an epoxy resin, or a sheet-like electrical insulating material such as an electrical insulation paper or an electrical insulation film generally used in electronic components.

As for a sheet-like electrical insulating material, for example, raw materials such as aramid fibers, cellulose fibers, and synthetic fibers (polyester fibers, polyimide fibers) may be used alone or in combination. The electrical insulation paper is, for example, an aramid paper having aramid fibers as a raw material, a cellulose paper having cellulose fibers as a raw material, etc. The electrical insulation film is, for example, a polyethylene terephthalate (PET) film containing PET. The sheet-like electrical insulating material has a thickness of, for example, 0.3 mm or more and may be applied in multiple sheets to achieve a thickness of, for example, about 1.0 mm. The insulating layer 8 may be formed by applying multiple sheet-like electrical insulating materials of different raw materials.

In the fabrication of the semiconductor module 10, first, the back surface of the semiconductor chip 1 (back electrode) is bonded, via the bonding member 11, to the conductive plate 22a constituting the front surface of the circuit board 2. Next, each LF bonding portion 5a of the single LF 5 is bonded, via the bonding members 13, 14, respectively, to the electrode pad 1a (front electrode) of the semiconductor chip 1 and the electrode pad 2a (the conductive plate 22b) of the circuit board 2, whereby the electrode pads 1a, 2a are electrically connected to each other by the LF 5. Next, the back surface of the circuit board 2 is bonded to the front surface of the cooling base 3, via the bonding member 12. Next, the case 4 is adhered to the outer edge of the cooling base 3, and the circuit board 102 is housed in the case 4 (in the recess 7). Thereafter, the members housed in the recess 7 are protected by the encapsulating material 6 and the insulating layer 8.

In the formation of the encapsulating material 6 and the insulating layer 8, when the insulating layer 8 is formed by a resin material, a resin material constituting the encapsulating material 6 is injected into the recess 7 and is cured; thereafter, in the recess 7, a resin material constituting the insulating layer 8 is injected onto the encapsulating material 6 and is cured. When the insulating layer 8 is formed by a sheet-like electrical insulating material, a resin material constituting the encapsulating material 6 (6a) is injected into the recess 7 and is cured; thereafter, the top surface of the encapsulating material 6a is covered by a sheet-like electrical insulating material constituting the insulating layer 8. Further, in the recess 7, the resin material constituting the encapsulating material 6 (6b) may be injected onto the resin material constituting the sheet-like electrical insulating material and cured (refer to FIG. 4). The encapsulating material 6b suppresses peeling of the sheet-like electrical insulating material (the insulating layer 8) while the encapsulating material 6 enhances insulation.

Even in the instance in which the insulating layer 8 is formed by a resin material, configuration may be such that the encapsulating material 6a, the insulating layer 8, and the encapsulating material 6b are formed in this sequence by alternately performing injection of the resin material into the recess 7 and curing, repeatedly (refer to FIG. 4). In an instance in which the LF 5 is provided in plural in the recess 7 (not depicted), the insulating layer 8 may be disposed singularly facing all of the LFs 5 in the vertical direction or the insulating layer 8 may be disposed in plural, each facing a corresponding one of the LFs 5 in the vertical direction. The bonding members 11 to 14 are, for example, conductive layers containing solder, a metal sintering material, etc.

As described above, in the semiconductor module 10 according to the first embodiment, the insulating layer 8 is provided facing the upper end 5b-1 of the LF rising portion 5b, whereby during a power cycling test, strain of the front electrode of the semiconductor chip 1 due to thermal expansion of the semiconductor chip 1 and the members in a vicinity thereof (the bonding member 13 and the LF bonding portion 5a) may be suppressed. A reason for this is as follows. The power cycling test is a test for evaluating bonding reliability between members in the semiconductor module 10, by alternately raising (self-heating of the semiconductor chip 1) and lowering (natural heat dissipation: cooling of the semiconductor chip 1) the junction temperature of a semiconductor device by intermittently energizing the semiconductor device fabricated in the semiconductor chip 1 so that the junction temperature varies within a predetermined temperature difference ΔTᵥⱼ.

When the semiconductor chip 1 generates heat due to energization of the semiconductor device fabricated in the semiconductor chip 1, the front electrode of the semiconductor chip 1, the bonding member 13, and the LF bonding portion 5a thermally expand in the vertical direction, whereby the top surfaces move upward (in a direction away from the circuit board 2). Movement of the LF rising portion 5b of the LF 5 in the vertical direction is facilitated by the insulating layer 8. When the front electrode of the semiconductor chip 1, the bonding member 13, and the top surface of the LF bonding portion 5a move upward due to thermal expansion, the LF rising portion 5b is pushed by the semiconductor chip 1 and also easily moves upward, thereby suppressing a concentration of stress at the lower end 5b-2 of the LF rising portion 5b. Thus, when the semiconductor chip 1 generates heat, deformation (deflection) of the LF rising portion 5b may be suppressed.

During cooling of the semiconductor chip 1, the encapsulating material 6 cools, shrinks, and plastically deforms, thereby pushing the semiconductor chip 1, the bonding member 13, and the LF bonding portion 5a downward (direction to the circuit board 2). Movement of the LF rising portion 5b of the LF 5 in the vertical direction is facilitated by the insulating layer 8. Further, the LF rising portion 5b, as described above, is not easily deformed by the heat generated by the semiconductor chip 1 and maintains nearly the same length as that before the power cycling test. Therefore, even when the semiconductor chip 1 is pushed downward by the encapsulating material 6, the end of the front electrode of the semiconductor chip 1 is not easily pulled upward by the LF rising portion 5b. Thus, directly beneath the lower end 5b-2 of the LF rising portion 5b, strain at the end of the front electrode of the semiconductor chip 1 is suppressed.

As described, according to the first embodiment, the insulating layer is provided facing the top surface of the LF connecting portion in the vertical direction so as to at least face the upper end of the LF rising portion in the vertical direction. The insulating layer is formed by an insulating material having a smaller elastic modulus than the elastic modulus of the encapsulating material. The insulating layer reduces the support of the LF rising portion by the encapsulating material and thus, even when stress that pushes the LF rising portion upward is generated by thermal expansion of the semiconductor chip, the LF rising portion easily moves upward and is not easily deformed. Thus, stress does not easily concentrate at the end of the front electrode of the semiconductor chip and the amount of strain applied to the end of the front electrode of the semiconductor chip is reduced. Therefore, the reliability of the front electrode of the semiconductor chip is enhanced, thereby enhancing the reliability of the semiconductor module. Further, even when heat generation and cooling of the semiconductor chip are repeatedly performed alternately, the front electrode of the semiconductor chip does not easily degrade and the power cycling capability may be enhanced.

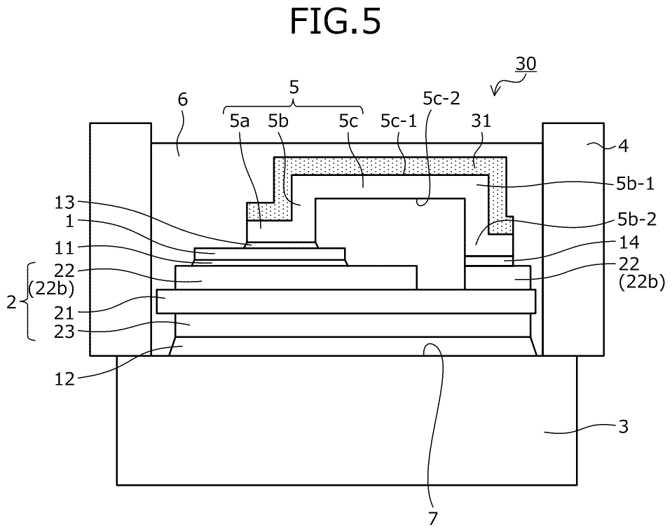

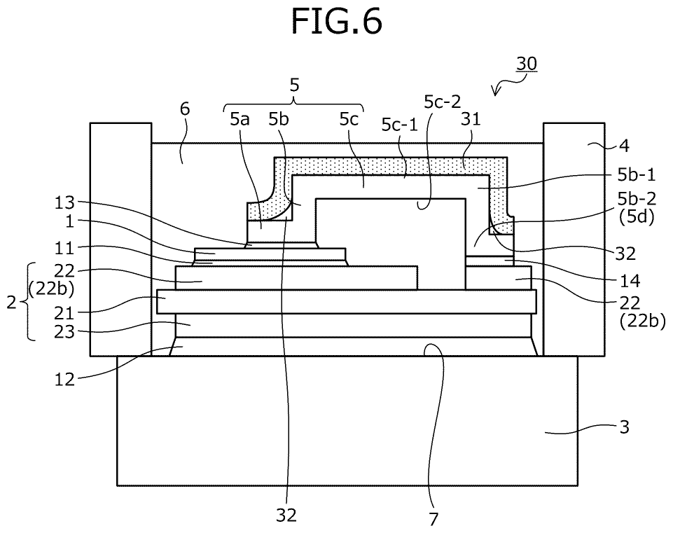

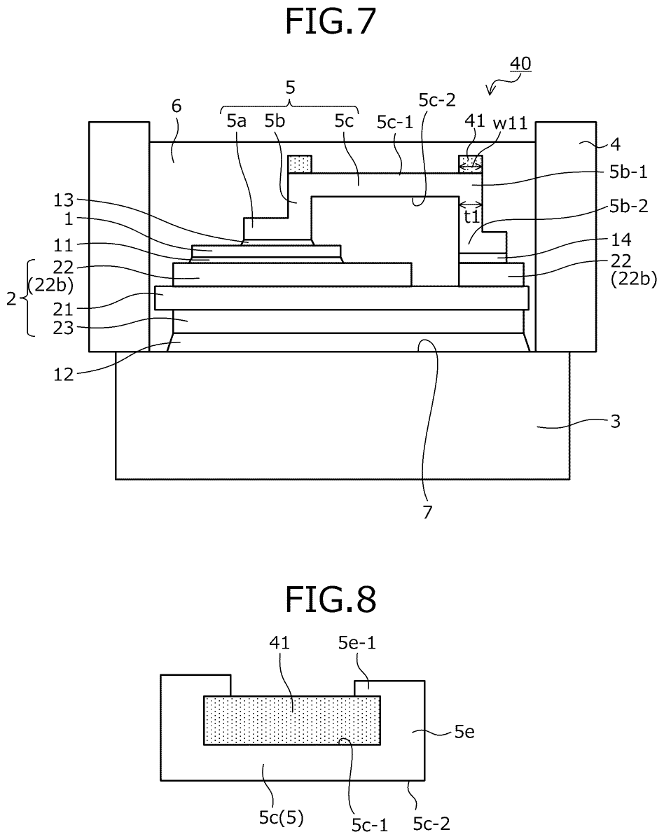

A semiconductor module according to a second embodiment solving the problems above is described. FIGS. 5 and 6 are cross-sectional views depicting a structure of the semiconductor module according to the second embodiment. FIGS. 7 and 8 are cross-sectional views depicting another example of the structure of the semiconductor module according to the second embodiment. In semiconductor modules 30, 40 according to the second embodiment depicted in FIGS. 5 and 7, in a cross-sectional view, shapes of insulating layers (hatched portions) 31, 41 facing the top surface 5c-1 of the LF connecting portion 5c in the vertical direction are different from the shape of the insulating layer 8 in the semiconductor module 10 according to the first embodiment (refer to FIGS. 3 and 4). Other than the shape of the insulating layer 31 in a cross-section view, configuration is a same as that of, the insulating layer 8 in the first embodiment.

In the semiconductor module 30 according to the second embodiment depicted in FIG. 5, the insulating layer 31 extends along the top surface of the LF 5 and has a shape in a cross-sectional view substantially a same as the shape of the LF 5. The insulating layer 31 is in contact with the top surface of the LF bonding portion 5a, a top surface (surface connecting the top surface of the LF bonding portion 5a and the top surface 5c-1 of the LF connecting portion 5c) of the LF rising portion 5b and the top surface 5c-1 of the LF connecting portion 5c, thereby covering substantially an entire area of the top surface of the LF 5. The insulating layer 31 may be covered overall by the encapsulating material 6 or may be exposed outside the encapsulating material 6, at a portion on the top surface 5c-1 of the LF connecting portion 5c.

The insulating layer 31, for example, may be easily formed using a sheet-like electrical insulating material. In an instance in which the insulating layer 31 is formed using a sheet-like electrical insulating material, first, by die-cutting and cut-out, a sheet-like electrical insulating material having a predetermined shape in a plan view is formed. Then, a resin material constituting the encapsulating material 6 may be injected into the recess 7 and cured; a sheet-like electrical insulating material constituting the insulating layer 31 may be disposed on the LF 5; and thereafter, again, the resin material constituting the encapsulating material 6 may be injected onto the sheet-like electrical insulating material and cured.

When the sheet-like electrical insulating material constituting the insulating layer 31 is apart from the top surface of the LF 5 near a bent portion 5d (the lower end 5b-2 of the LF rising portion 5b) between the LF bonding portion 5a and the LF rising portion 5b (FIG. 6), a space between the sheet-like electrical insulating material constituting the insulating layer 31 and the LF 5 may be filled with a resin material 32 before the resin material constituting the encapsulating material 6 is again injected into the recess 7. The resin material 32 may be an epoxy resin or the like having an elastic modulus smaller than the elastic modulus of the encapsulating material 6 or may be the same resin material at the resin material constituting the encapsulating material 6. The encapsulating material 6 may intervene between the insulating layer 31 and the LF 5.

In the semiconductor module 40 according to the second embodiment depicted in FIG. 7, the insulating layer 41 is disposed only on the upper end 5b-1 of the LF rising portion 5b. When the insulating layer 41 is disposed on the upper end 5b-1 of the LF rising portion 5b, it is presumed that support of the LF rising portion 5b by the encapsulating material 6 is reduced. The insulating layer 41 may face the upper end 5b-1 of the LF rising portion 5b in the vertical direction, via the encapsulating material 6. Other than the shape of the insulating layer 41 in a cross-sectional view, configuration is the same as the configuration of the insulating layer 8 in the first embodiment. The insulating layer 41 may extend beyond an outer periphery of the upper end 5b-1 of the LF rising portion 5b, in particular, the greater a length w11 of the insulating layer 41 extending along the top surface 5c-1 of the LF connecting portion 5c in a longitudinal direction of the LF connecting portion 5c exceeds a thickness t1 of the LF 5 (the LF rising portion 5b), the greater is the effect by the insulating layer 41.

At the upper end 5b-1 of the LF rising portion 5b, a hook-shaped part 5e may be provided (FIG. 8). The hook-shaped part 5e protrudes upward from the top surface 5c-1 of the LF connecting portion 5c and has, in a cross-sectional view, a hook-like shape curved toward a center of the LF connecting portion 5c in a lateral direction. The hook-shaped part 5e is provided at both opposing ends of the top surface 5c-1 of the LF connecting portion 5c in the lateral direction. The hook-shaped part 5e has a portion 5e-1 curved toward the center of the LF connecting portion 5c in the lateral direction and has a function of preventing the insulating layer 41 from falling from the LF 5 during an assembly process by holding the insulating layer 41 (sheet-like electrical insulating material) between the portions 5e-1 and the upper end 5b-1 of the LF rising portion 5b. The hook-shaped part 5e may extend along the opposing ends (in the lateral direction) of the top surface 5c-1 of the LF connecting portion 5c.

As described, according to the second embodiment, the insulating layer suffices to face the upper end of the LF rising portion in the vertical direction, whereby effects similar to those of the first embodiment may be obtained.

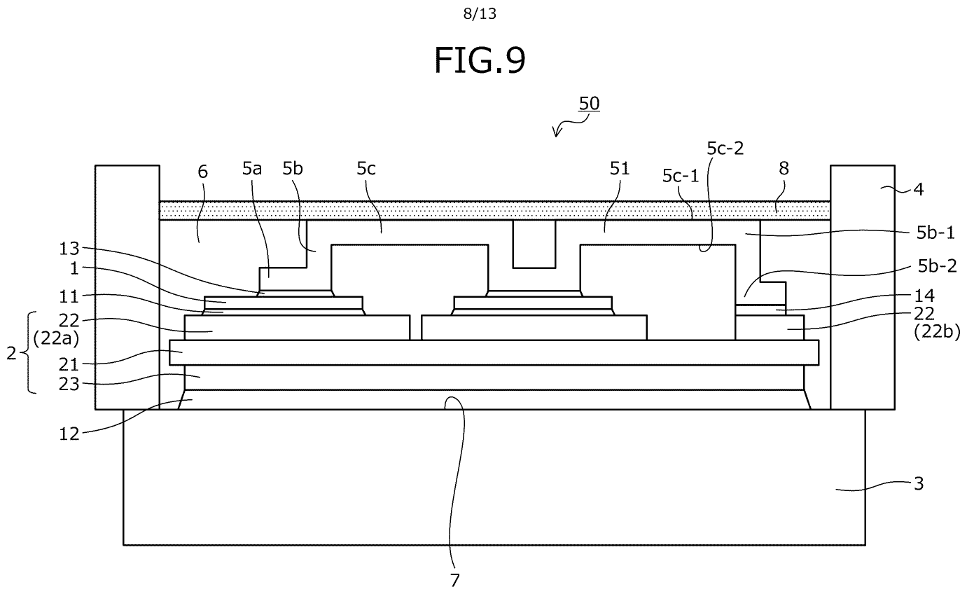

A semiconductor module according to a third embodiment solving the problems above is described. FIG. 9 is a cross-sectional view depicting a structure of the semiconductor module according to the third embodiment. A semiconductor module 50 according to the third embodiment differs from the semiconductor module according to the first embodiment (FIGS. 3 and 4) in that multiple front electrodes (the electrode pads 1a) of multiple semiconductor chips 1 mounted on the circuit board 2 and the conductive plate 22b (the electrode pad 2a) of the front surface of the circuit board 2 are electrically connected to each other by a single LF 51.

The LF 51 has the LF bonding portion 5a, the LF rising portion 5b, and the LF connecting portion 5c, which are the same as in the first embodiment and provided in quantities necessary to electrically connect the electrode pads 1a, 2a of a predetermined number on the circuit board 2 to one another. Similar to the first embodiment, the LF 51 extends between the semiconductor chips 1 that are adjacent to one another and extends between the semiconductor chips 1 and the conductive plate 22b that are adjacent to each other, so that the LF 51 includes, in a cross-sectional view, a substantially Z-shape formed by the LF bonding portion 5a, the LF rising portion 5b, and the LF connecting portion 5c.

The insulating layer 8 is provided at a first side of the LF 51, opposite to a second side thereof facing the circuit board 2, the insulating layer 8 facing the top surfaces 5c-1 of all the LF connecting portions 5c in the vertical direction. The insulating layer 8 may be provided singularly facing the top surfaces 5c-1 of all the LF connecting portions 5c of the LF 51 in the vertical direction or the insulating layer 8 may be provided in plural, each facing the top surface 5c-1 of a corresponding one of the LF connecting portions 5c of the LF 51 in the vertical direction. In other words, the insulating layer 8 may face the LF 51 overall in the vertical direction or may face only the top surface 5c-1 of each of the LF connecting portions 5c of the LF 51 in the vertical direction.

The second embodiment may be applied to the semiconductor module 50 according to the third embodiment, the insulating layer may extend along the top surface of the LF 51 and the insulating layer having substantially a same shape as the shape of the LF 51 in a cross-sectional view may be provided (refer to the insulating layer 31 in FIGS. 5 and 6), or the insulating layer may be disposed only at portions facing the upper ends 5b-1 of the LF rising portions 5b of the LF 51 in the vertical direction (refer to the insulating layer 41 in FIG. 7), or the hook-shaped part for supporting the insulating layer may be provided at the upper ends 5b-1 of the LF rising portions 5b of the LF 51 (refer to the hook-shaped part 5e in FIG. 8).

As described, according to the third embodiment, even when multiple semiconductor chips are electrically connected to one another, effects similar to the effects of the first embodiment may be obtained.

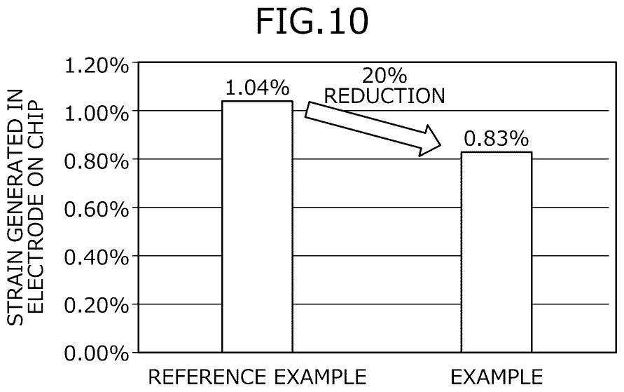

A first verification example is described. The power cycling capability of the semiconductor module 10 according to the first embodiment was verified. FIG. 10 is a graph showing results of simulation of the amount of strain of a front electrode of a semiconductor chip in an example and a reference example. Simulation of a power cycling test of a semiconductor module (hereinafter, the example) having the structure of the semiconductor module 10 according to the first embodiment (refer to FIGS. 1 to 3) was performed by a finite element method (FEM) analysis and calculated results of the strain amount (here, strain amount=deformation amount in the vertical direction/original thickness) of the front electrode of the semiconductor chip 1 are shown in FIG. 10.

For example, when focusing on the amount of deformation in the vertical direction in the structure as shown in FIG. 10, the strain amount of the semiconductor chip 1 may be a vertical strain and may be equivalent strain when a comprehensive strain is extracted. The comprehensive strain is strain with multiple plastic components having principal axes in, respectively, different directions. Equivalent strain is a plastic component in a predetermined axial direction of strain that occurs repeatedly due to repeated loading during power cycling. In other words, the strain amount of the front electrode of the semiconductor chip 1 is the amount of deformation (=deformation amount/original thickness) in the predetermined axial direction (excluding directions parallel to the front surface of the circuit board 2) of the front electrode with respect to the original thickness (height from the front surface of the semiconductor chip 1) of the front electrode.

In the simulated power cycling test, the temperature difference ΔTᵥⱼ of the maximum temperature and the minimum temperature of a junction temperature Tᵥⱼ of a semiconductor device due to intermittent energization of the semiconductor device, which is fabricated in the semiconductor chip 1, is assumed to be 135 degrees C. The maximum temperature of the junction temperature Tᵥⱼ during temperature rise of the semiconductor device due to generated heat (self-heating) of the semiconductor chip 1 was assumed to be 175 degrees C. and the minimum temperature of the junction temperature Tᵥⱼ during cooling of the semiconductor device by cooling (natural heat dissipation) of the semiconductor chip 1 was assumed to be 40 degrees C. The temperature at which stress from the semiconductor chip 1 is not applied to the LF rising portion 5b of LF 5 was assumed to be 40 degrees C. The heating time and cooling time of the semiconductor chip 1 were 1 second and 9 seconds, respectively.

The insulating layer 8 has substantially a same shape as the shape of the top surface 5c-1 of the LF connecting portion 5c in a plan view and is in contact with an entire area of the top surface 5c-1 of the LF connecting portion 5c. The thickness t1 of the LF 5 was assumed to be 0.5 mm. The height h of the LF rising portion 5b was assumed to be 2.0 mm. The width w1 of the LF bonding portion 5a and the width w2 of the LF rising portion 5b were assumed to be 3.0 mm. The width w3 of the LF connecting portion 5c was assumed to be 2.5 mm. The semiconductor material of the semiconductor chip 1 was SiC. Under the same conditions as the conditions of the example, the strain amount of the front electrode of the semiconductor chip 101 was calculated for a semiconductor module (hereinafter, simply, the reference example) having the structure of the semiconductor module 110 according to the reference example (refer to FIG. 13). Other than being free of the insulating layer 8, the reference example has the same structure as the structure of the example.

As depicted in FIG. 10, the example was confirmed to reduce the strain amount of the front electrode of the semiconductor chip 1 about 20% in the power cycling test as compared to the reference example. Thus, it was confirmed that the power cycling capability is enhanced by the insulating layer 8 and the reliability may be ensured.

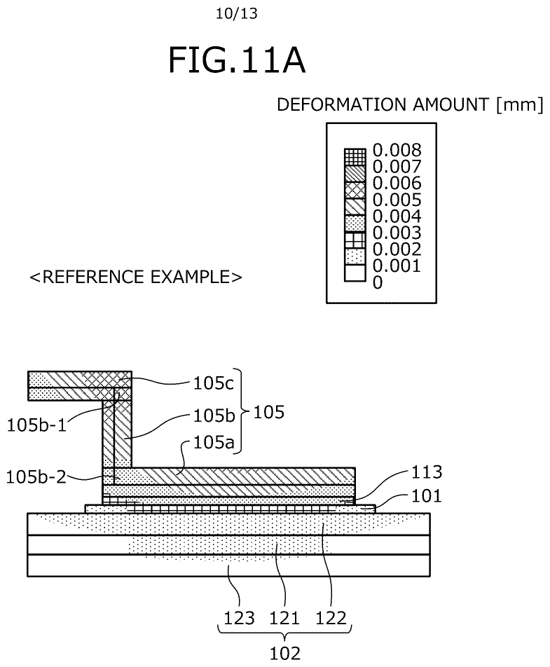

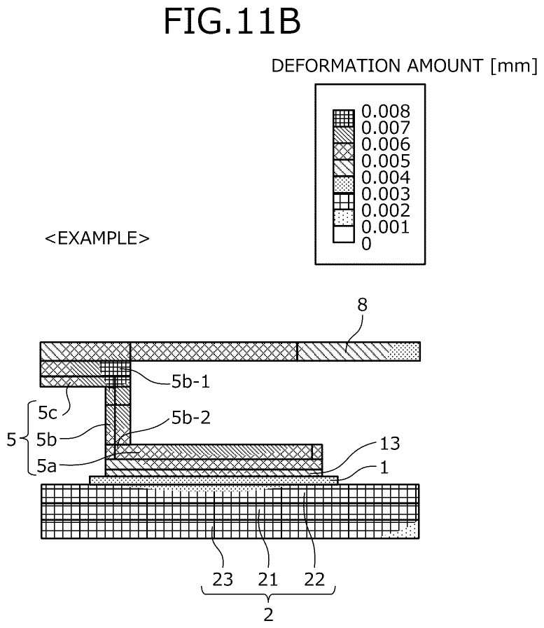

A second verification example is described. The amount of deformation in the vertical direction of the semiconductor chip 1 and the members in a vicinity thereof in the semiconductor module 10 according to the first embodiment was verified. FIGS. 11A and 11B are contour diagrams depicting results of simulation of a state during deformation caused by thermal stress of members in the semiconductor module of the example and the semiconductor module of the reference example. FIGS. 11A and 11B depict the deformation amounts in the vertical direction of the semiconductor chips 1, 101 and the members in a vicinity thereof (the bonding members 13, 113 and the LFs 5, 105) in the semiconductor modules 10, 110 when the power cycling test was simulated under the respective simulation conditions described above for the example and the reference example.

As depicted in FIGS. 11A and 11B, in the reference example, the deformation amount in the vertical direction was about the same in substantially an entire area of the LF 5. On the other hand, in the example, the maximum deformation at the upper end 5b-1 of the LF rising portion 5b was greater than the maximum deformation in the reference example. It is presumed that the insulating layer 8 is provided, whereby support of the LF rising portion 5b by the encapsulating material 6 is reduced and the LF rising portion 5b easily moves upward when the LF rising portion 5b is pushed upward by the semiconductor chip 1 that has thermally expanded. It is presumed that the LF rising portion 5b moves upward, whereby the point of concentration of stress due to thermal expansion of the semiconductor chip 1 moves to the upper end 5b-1 of the LF rising portion 5b.

A third verification example is described. The thickness t2 of the insulating layer 8 was verified. FIG. 12 is a characteristics diagram depicting results of simulation of a relationship between the strain amount of the front electrode of the semiconductor chip and the thickness of the respective insulating layers of the example and the reference example. In the example described above, the relationship between the thickness t2 of the insulating layer 8 and the strain amount of the front electrode of the semiconductor chip 1 when the power cycling test was simulated under the simulation conditions described above while the thickness t2 of the insulating layer 8 was variously changed is depicted in FIG. 12. In FIG. 12, a result of simulation when the thickness t2 of the insulating layer 8=0 mm is the strain amount of the front electrode of the semiconductor chip 101 in the reference example described above.

As depicted in FIG. 12, the thicker is the thickness t2 of the insulating layer 8, the lower is the strain amount of the front electrode of the semiconductor chip 1. It is presumed that increases in the thickness t2 of the insulating layer 8 lower the support of the LF rising portion 5b by the encapsulating material 6.

In the foregoing, without limitation by the embodiments, the present disclosure may be variously modified within a range not departing from the spirit of the disclosure and is applicable in instances in which one or more semiconductor chips of various types of configurations and having a front electrode is mounted in a semiconductor module.

The semiconductor module according to the present disclosure achieves an effect in that power cycling capability may be enhanced.

As described, the semiconductor module according to the present disclosure is useful for power semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor module, comprising:
a stacked substrate having, at a top surface thereof, a conductive plate;
a semiconductor chip having a front surface and a back surface opposite to each other, the back surface being bonded to the top surface of the stacked substrate, the semiconductor chip having a front electrode at the front surface;
a lead frame electrically connecting the front electrode and the conductive plate to each other, the lead frame having a first surface and a second surface opposite to each other, the second surface facing the stacked substrate;
an encapsulating material encapsulating the semiconductor chip, the stacked substrate, and the lead frame; and
an insulating layer provided on the lead frame, and facing the first surface of the lead frame in a thickness direction of the semiconductor chip, wherein
the insulating layer contains an electrical insulating material having an elastic modulus smaller than an elastic modulus of the encapsulating material.

2. The semiconductor module according to claim 1, wherein the insulating layer faces an entire area of the first surface of the lead frame.

3. The semiconductor module according to claim 1, wherein the insulating layer is in contact with the lead frame.

4. The semiconductor module according to claim 1, wherein the insulating layer has a thickness in a range of 0.2 mm to 0.5 mm.

5. The semiconductor module according to claim 1, wherein
the lead frame has:
a bonding portion bonded to the front electrode,
a connecting portion electrically connected to the conductive plate, and
a rising portion extending in the thickness direction to connect the bonding portion and the connecting portion, wherein
each of the bonding portion, the connecting portion and the rising portion is of a plate shape,
the rising portion has a first end and a second end opposite to each other, the first end and the second end being respectively connected to an end of the bonding portion and an end of the connecting portion, and
the insulating layer faces the second end of the rising portion in the thickness direction of the semiconductor chip.

6. The semiconductor module according to claim 5, wherein
the connecting portion has a first surface and a second surface opposite to each other, the second surface facing the stacked substrate, and
the insulating layer is in contact with an entire area of the first surface of the connecting portion.

7. The semiconductor module according to claim 6, wherein
the bonding portion has a first surface and a second surface, the second surface of the bonding portion being bonded to the front electrode, and
the insulating layer extends from the connecting portion, along the rising portion, to the first surface of the bonding portion.

8. The semiconductor module according to claim 5, wherein the insulating layer is provided only at the second end of the rising portion.

9. The semiconductor module according to claim 8, wherein
the second end of the rising portion has a hook-shaped part, and
the insulating layer is formed in the hook-shaped part.
